(19) United States
(12) Patent Application Publication
(10) Pub. No.: US 2007/0026144 A1
(43) Pub. Date: Feb. 1, 2007

(54) Method of depositing thin film on wafer

(76) Inventors: Young Hoon Park, Kyungki-do (KR); Sahng Kyoo Lee, Kyungki-do (KR); Tae Wook Seo, Kyungki-do (KR); Ho Seung Chang, Kyungki-do (KR)

Correspondence Address: CANTOR COLBURN, LLP, 55 GRIFFIN ROAD SOUTH, BLOOMFIELD, CT, 06002, US

(21) Appl. No.: 10/569,929

(22) PCT Filed: Aug. 28, 2004
(86) PCT No.: PCT/KR04/02166

§ 371 Date: Feb. 27, 2006

(30) Foreign Application Priority Data
Aug. 29, 2003 (KR) 10-2003-0060240

(51) Int. Cl. C23C 16/00

(52) U.S. Cl. 427/248.1

(57) ABSTRACT

Provided is a method of depositing a thin film. The method is performed using a thin film deposition apparatus that includes a reaction chamber having a wafer block located in a chamber to heat a loaded wafer up to a predetermined temperature, a top lid covering the chamber to seal the chamber, and shower head coupled under the top lid and having a first injection hole and a second injection hole, through which a first reaction gas and a second reaction gas are injected into the wafer, a reaction gas supplying unit supplying the first and second reaction gases into the reaction chamber, and a gas heating path unit installed on a second conveying line between first and second conveying lines connecting the reaction chamber and the reaction gas supplying unit to heat the gas passing through itself, and the method includes the operations of: loading the wafer on the wafer block; depositing a thin film by injecting the first reaction gas and the second reaction gas that is thermally activated onto the wafer through the first and second injection holes; flowing a heat treatment gas including an H element onto the thin film to reduce impurities included in the thin film; and unloading the wafer, on which the thin film is deposited, from the wafer block. If the second reaction gas has a temperature of T1 before passing through the gas heating path unit and a temperature of T2 after passing through the gas heating path unit, T2 is higher than T1, and if the heat treatment gas has a temperature of T1 before passing through the gas heating path unit and a temperature of T3 after passing through the gas heating path unit, T3 is same as T1 or higher.

### TECHNICAL FIELD

The present invention relates to a method of depositing a thin film, and more particularly, to a method of depositing a thin film on a wafer at low temperature so that impurities in the deposited thin film can be reduced.

### BACKGROUND ART

A chemical vapor deposition (CVD) method or an atomic layer deposition (ALD) method are methods of depositing a thin film using a thin film deposition apparatus based on a chemical reaction. In performing the CVD method or ALD method, manufacturers of semiconductor devices seeks to enlarge a wafer and achieve a superfine line width in a circuit in order to improve productivity of the semiconductor devices. Furthermore, various elements such as superiority of a thin film that is deposited on the substrate, price of apparatus for depositing thin film, operating rate of equipment, maintaining costs, and the number of wafers processed per hour are considered to improve the productivity. One of the indexes that represent the above elements is the cost of ownership (CoO), and it is important to lower the CoO for improving the productivity. In addition, ongoing efforts are focused on achieving a superfine line width and large substrate for lowering the CoO, and a temperature for a depositing process should be lowered in order to prevent characteristics of the semiconductor device from degrading.

### DISCLOSURE OF THE INVENTION

The present invention provides a method of depositing a thin film at a relatively low substrate temperature to reduce impurities in the deposited thin film.

According to an aspect of the present invention, there is provided a method of depositing a thin film using a thin film deposition apparatus that includes a reaction chamber having a wafer block located in a chamber to heat a loaded wafer up to a predetermined temperature, a top lid covering the chamber to seal the chamber, and a shower head coupled under the top lid and having a first injection hole and a second injection hole, through which a first reaction gas and a second reaction gas are injected into the wafer, a reaction gas supplying unit supplying the first and second reaction gases into the reaction chamber, and a gas heating path unit installed on a second conveying line between first and second conveying lines connecting the reaction chamber and the reaction gas supplying unit to heat the gas passing through itself, the method including the operations of: loading the wafer on the wafer block; depositing a thin film by injecting the first reaction gas and the second reaction gas that is thermally activated onto the wafer through the first and second injection holes; flowing a heat treatment gas including an H element onto the thin film to reduce impurities included in the thin film; and unloading the wafer, on which the thin film is deposited, from the wafer block. If the second reaction gas has a temperature of T1 before passing through the gas heating path unit and a temperature of T2 after passing through the gas heating path unit, T2 may be higher than T1, and if the heat treatment gas has a temperature of T1 before passing through the gas heating path unit and a temperature of T3 after passing through the gas heating path unit, T3 may be same as T1 or higher.

If the second reaction gas supplied from the reaction gas supplying unit has a temperature of T0 right after being induced into the second conveying line and a temperature of T2′ before being induced into the top lid, the gas heating path unit may be connected close to the top lid so that T2′ is lower than T2 and higher than T0.

If T2′ satisfies a relation of T2>T2′>T0, a value of T2′ - T0 may be at least 20° C. or higher.

In the flowing of the heat treatment gas, the heat treatment gas including H element may include one or more selected from the group consisting of N2, NH3, and N2H4.

According to another aspect of the present invention, there is provided a method of depositing a thin film using a thin film deposition apparatus that includes a reaction chamber having a wafer block located in a chamber to heat a loaded wafer up to a predetermined temperature, a top lid covering the chamber to seal the chamber, a shower head coupled under the top lid and having a first injection hole and a second injection hole, through which a first reaction gas and a second reaction gas are injected into the wafer, and a fluid path circulating a fluid into the top lid or the shower head, a reaction gas supplying unit supplying the first and second reaction gases into the reaction chamber, and a gas heating path unit installed on a second conveying line between first and second conveying lines connecting the reaction chamber and the reaction gas supplying unit to heat the gas passing through itself, and the method including the operations of: loading the wafer on the wafer block; depositing a thin film by injecting the first reaction gas including a transition element and the second reaction gas that is thermally activated onto the wafer through the first and second injection holes; and unloading the wafer, on which the thin film is deposited, from the wafer block. If the second reaction gas has a temperature of T1 before passing through the gas heating path unit and a temperature of T2 after passing through the gas heating path unit, T2 may be higher than T1, and the fluid may flow through the fluid path to control a surface temperature of the shower head.

A thermocouple may be installed on the shower head or the top lid for measuring the temperature of the shower head, and a flowing amount on the fluid path may be varied from a signal generated by the thermocouple, so that a value of maximum temperature—minimum temperature at any point on the lowermost surface of the shower head can be maintained within a range of ±25° C.

According to still another aspect of the present invention, there is provided a method of depositing a thin film using a thin film deposition apparatus that includes a reaction chamber having a wafer block located in a chamber to heat a loaded wafer up to a predetermined temperature, a top lid covering the chamber to seal the chamber, a shower head coupled under the top lid and having a first injection hole and a second injection hole, through which a first reaction gas and a second reaction gas are injected into the wafer, and a fluid path circulating a fluid into the top lid or the shower head, a reaction gas supplying unit supplying the first and second reaction gases into the reaction chamber, a first gas heating path unit installed on a first conveying line connecting the reaction chamber and the reaction gas supplying unit to heat the gas passing through itself, and a second gas heating path unit installed on a second conveying line connecting the reaction chamber and the reaction gas supplying unit to heat the gas passing through itself, the method including the operations of: loading the wafer on the wafer block; depositing a thin film by injecting the first reaction gas that is thermally activated and the second reaction gas that is thermally activated onto the wafer through the first and second injection holes; and unloading the wafer, on which the thin film is deposited, from the wafer block. If the first reaction gas has a temperature of T1 before passing through the first gas heating path unit and a temperature of T2 after passing through the first gas heating path unit, T2 may be smaller than a decomposition temperature of the first reaction gas, if the second reaction gas has a temperature of T3 before passing through the second gas heating path unit and a temperature of T4 after passing through the second gas heating path unit, T4 may be the decomposition temperature of the second reaction gas or higher, and the fluid may flow through the fluid path to control a surface temperature of the shower head.

A thermocouple may be installed on the shower head or the top lid for measuring the temperature of the shower head, and a flowing amount on the fluid path may be varied from a signal generated by the thermocouple, so that a value of maximum temperature—minimum temperature at any point on the lowermost surface of the shower head can be maintained within a range of ±25° C.

The depositing of thin film may include: feeding the gas by injecting the first reaction gas regularly and repeatedly through the first injection hole while injecting the second reaction gas onto the wafer through the second injection hole; and injecting a purge gas through the first injection hole between the feeding periods of the first reaction gas.

The depositing of the thin film may include: feeding the gas by injecting the first and second reaction gases through the first and second injection holes regularly and alternately, and injecting the purge gas through the first injection hole and/or the second injection hole between the feeding periods of the first and second reaction gases.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic block diagram showing a first embodiment of a thin film deposition apparatus for performing a method of depositing the thin film according to the present invention;

FIG. 2 is a block diagram showing an example of a gas heating path adopted in the thin film deposition apparatus shown in FIG. 1;

FIG. 3 is a block diagram showing another example of the gas heating path adopted in the thin film deposition apparatus shown in FIG. 1;

FIG. 4 is a schematic block diagram showing a second embodiment of a thin film deposition apparatus for performing the method of depositing the thin film according to the present invention;

FIG. 5 is a schematic block diagram showing a third embodiment of the thin film deposition apparatus for performing the method of depositing the thin film according to the present invention;

FIG. 6 is a graph showing an example of a thin film deposition process in the method of depositing thin film according to the present invention; and

FIG. 7 is a graph showing another example of a thin film deposition process in the method of depositing thin film according to the present invention.

### BEST MODE FOR CARRYING OUT THE INVENTION

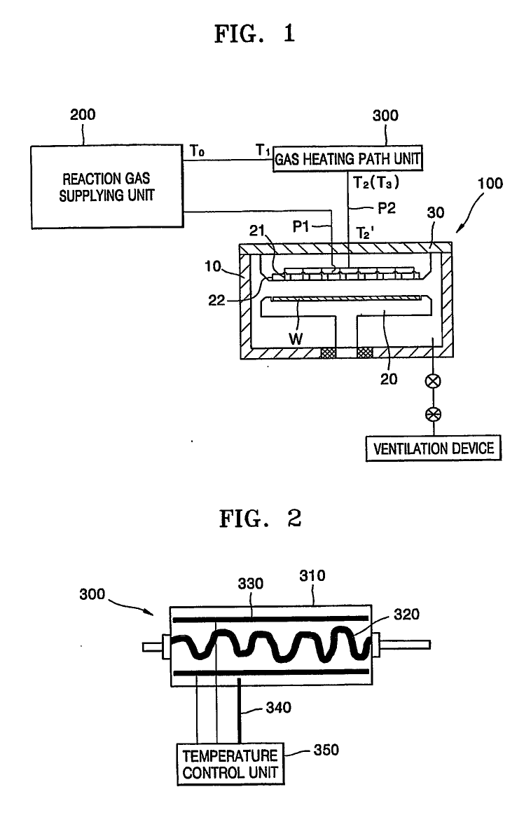

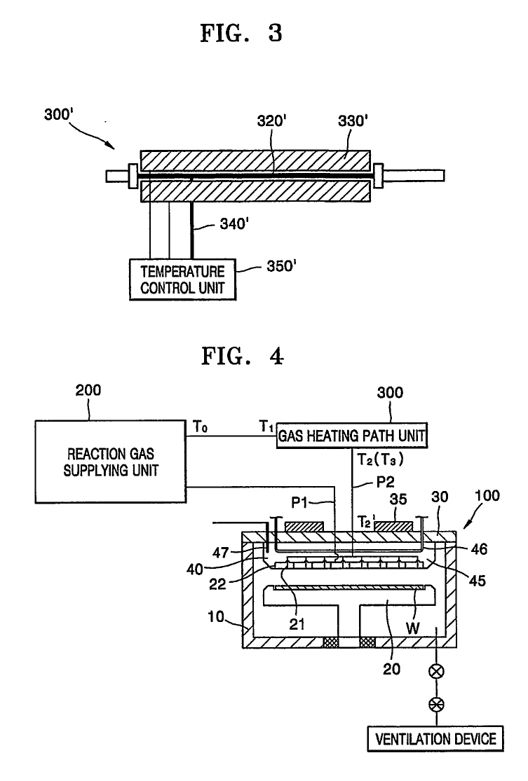

FIG. 1 is a schematic block diagram showing a first embodiment of a thin film deposition apparatus for performing a method of depositing thin film according to the present invention, FIG. 2 is a block diagram showing an example of a gas heating path unit adopted in the thin film deposition apparatus shown in FIG. 1, and FIG. 3 is a block diagram showing another example of the gas heating path unit adopted in the thin film deposition apparatus shown in FIG. 1.

As shown in FIG. 1, the thin film deposition apparatus includes a reaction chamber 100, in which a thin film is deposited, and a reaction gas supplying unit 200 that generates a reaction gas that is supplied to the reaction chamber 100. Here, the gas heating path unit 300 is installed on a conveying line P2 that conveys a second reaction gas between two conveying lines P1 and P2 between the reaction chamber 100 and the reaction gas supplying unit 200.

The reaction chamber 100 includes a wafer block 20 positioned in a chamber 10 for heating a loaded wafer W to a predetermined temperature, a top lid 30 covering the chamber 10 to seal the chamber 10, and a shower head 40 coupled to the top lid 30 under the top lid 30 for injecting a first reaction gas and the second reaction gas onto the wafer W. Here, an injecting surface is formed on a bottom surface of the shower head 40, and a plurality of first and second injection holes 21 and 22 for injecting the first and second reaction gases are formed on the injecting surface so as not to contact each other.

The reaction gas supplying unit 200 induces the first reaction gas that is controlled to be in a vapor state from a canister (not shown), in which a liquid material of the thin film is contained, into the reaction chamber 100 through the conveying line P1. The second reaction gas, that is, the gas source, is induced into the reaction chamber 100 through the second conveying line P2.

As shown in FIG. 2, the gas heating path unit 300 includes a housing 310, a conduit 320 having a straight or curved shape, formed in the housing 310, and in which the gas flows, and a cartridge heater 330 is installed around the conduit 320 or a hot wire is wound on the conduit 320. The gas passing through the conduit 320 is heated up to at least 200° C. In addition, a thermocouple 340 is installed on the housing 310 for measuring the temperature of the gas heating path unit 300, and a temperature control unit 350 that controls the temperature of the heater 330 based on the temperature information generated by the thermocouple 340 is connected to the housing 310.

As shown in FIG. 3, another example of the gas heating path unit 300′ includes a jacket heater 330′, in which the conduit 320′ is formed, and heats the gas passing through the conduit 320′ up to at least 2000C. In addition, a thermocouple 330′ is coupled on the jacket heater 330′ for measuring the temperature of the gas heating path unit 300′, and a temperature control unit 350′, that controls the temperature of the jacket heater 330′ based on the temperature information generated by the thermocouple 340′, is connected to the jacket heater 330′.

A cooling block may be mounted on an outmost portion of the housing 310 and a coolant such as water, air, or oil can flow on the cooling block, although the cooling block is not shown in the drawings. Thus, if a user touches the gas heating path unit 300 or 300′ by hand, he/she is not burned. Otherwise, a safety cover can cover the housing 310 so that the user cannot touch the housing 310.

It is difficult to heat the gas line up to 150° C. or higher using the blocked gas line or the conventionally arranged gas line. Even if the conveying line connecting the reaction gas supplying unit and the reaction chamber is about 30 cm or longer and a temperature zone where the gas can be heated about up to 150° C., the gas flows very fast, and it is difficult to heat the gas. That is, the temperature of the reaction gas when it starts from the conveying line and the temperature of the reaction gas when it is induced into the reaction chamber are hardly different from each other. Therefore, in the thin film deposition apparatus, the gas heating path unit 300 or 300′ including the conduit 320 or 320′ and the heater 330 or 330′ is adopted in order to thermally activate or thermally deactivate the gas. It is desirable that the gas heating path unit 300 be installed right above the top lid 30 in order to maximize the temperature efficiency.

FIG. 4 is a schematic block diagram showing a second embodiment of the thin film deposition apparatus for performing the method of depositing a thin film according to the present invention. Here, the same reference numerals as those in FIG. 1 denote the same elements having the same functions, and the apparatus includes the gas heating path unit shown in FIGS. 2 and 3.

As shown in FIG. 4, the thin film deposition apparatus includes the reaction chamber 100, in which the thin film is deposited, and the reaction gas supplying unit 200 that generates the reaction gas supplied to the reaction chamber 100. The gas heating path unit 300 is installed on the conveying line P2 that supplies the second reaction gas between the two conveying lines P1 and P2 that connect between the reaction chamber 100 and the reaction gas supplying unit 200.

The reaction chamber 100 includes the wafer block 20 that is positioned in the chamber 10 to heat the loaded wafer W up to a predetermined temperature, the top lid 30 that covers the chamber 10 to seal the chamber 10, and the shower head 40 coupled to the top lid 30 under the top lid 30 to inject the first and second reaction gases onto the wafer W. Here, the shower head 40 may be formed of aluminum in consideration of costs and processability, or can be formed of nickel further in consideration of corrosiveness.

However, when a temperature at a lowermost surface of the shower head 40 exceeds 320° C. during the thin film deposition process is performed, a warpage phenomenon occurs gradually arid corrosion is generated due to the deposited thin film. Also, the high temperature may directly cause generation of particles. Therefore, in order to reduce the warpage, corrosion, and the generation of particles on the shower head 40, a fluid path 46, by which fluid can be circulated in the top lid 30 or the shower head 40, is formed, and a thermocouple 47 for measuring the temperature of the shower head 40 is used.

The thermocouple 47 measures the temperature of the shower head 40, and generates a signal for controlling the fluid path 46 based on the measured temperature. Accordingly, a flowing amount of the fluid can be varied by the signal, thus the shower head 40 is not overheated, and the temperature of the shower head 40 can be maintained within a predetermined range. Thus, a value of the maximum temperature—the minimum temperature can be maintained within a range of ±25° C. at any portion of the lowermost surface of the shower head 40.

A surface heater 35 may be installed on an upper portion of the top lid 30 in order to control the temperature of the shower head 40 easily. The surface heater 35 maintains the surface temperature of the shower head 40 constant within a tolerable range by networking with the thermocouple 47 and the fluid path 46.

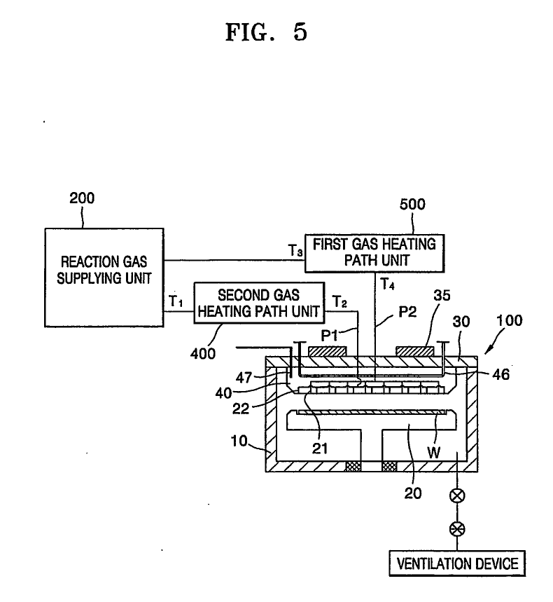

FIG. 5 is a schematic block diagram showing a third embodiment of the thin film deposition apparatus for performing the method of depositing the thin film according to the present invention. Here, the same reference numerals as those in FIG. 1 denote the same elements having the same functions, and the apparatus includes the gas heating path unit shown in FIGS. 2 and 3.

As shown in FIG. 5, the thin film deposition apparatus includes the reaction chamber 100, in which the thin film is deposited, and the reaction gas supplying unit 200 that generates the reaction gas supplied to the reaction chamber 100, a first gas heating path unit 400 installed on the first conveying line P1 connecting the reaction chamber 100 and the reaction gas supplying unit 200 for heating the gas passing through the first conveying line P1, and a second gas heating path unit 500 installed on the second conveying line P2 connecting the reaction chamber 100 and the reaction gas supplying unit 200 to heat the gas passing through the second conveying line P2.

The reaction chamber 100 includes the wafer block 20 that is positioned in the chamber 10 to heat the loaded wafer W up to a predetermined temperature, the top lid 30 that covers the chamber 10 to seal the chamber 10, and the shower head 40 coupled to the top lid 30 under the top lid 30 to inject the first and second reaction gases onto the wafer W. Here, the fluid path 46 is formed in the top lid 30 or the shower head 40 like in the second embodiment, and the thermocouple 47 and the surface heater 35 are adopted, however, detailed descriptions thereof are omitted.

In the third embodiment of the thin film deposition apparatus, the gas heating path unit is also formed on the first conveying line P1, as well as on the second conveying line P2. That is, the first gas heating path unit 400 is installed on the first conveying line P1, and the second gas heating path unit 500 is formed on the second conveying line P2, thus the first reaction gas also can be heated as well as the second reaction gas. The third embodiment of the thin film deposition apparatus is to obtain a chemical reactivity that can be obtained from a plasma enhanced CVD (PECVD) method or a pulsed plasma ALD method using the first and second gas heating path units 400 and 500.

The method of depositing the thin film according to the present invention will be described using the above described thin film deposition apparatus.

A first embodiment of the thin film deposition apparatus is performed using the first embodiment of the thin film deposition apparatus.

The method of depositing the thin film includes the operations of loading the wafer W on the wafer block (S1), depositing the thin film by injecting the first reaction gas including transition elements and the second reaction gas that is thermally activated by the gas heating path unit 300 through the first and second injection holes 21 and 22 (S2), post-processing the thin film to reduce the amount of impurities included in the thin film by flowing a heat treatment gas including H element onto the thin film after depositing the thin film (S3), and unloading the wafer W, on which the thin film is deposited, from the wafer block 20 after performing the post process (S4).

Here, assuming that the temperature of the second reaction gas is T1 before passing through the gas heating path unit 300 and the temperature of the second reaction gas is T2 after passing through the gas heating path unit 300, the temperature T2 should be higher than T1. In addition, if it is assumed that a temperature of the heat treatment gas is T1 before passing through the gas heating path unit 300 and the temperature of the heat treatment gas is T3 after passing through the gas heating path unit 300, T3 should be higher than T1.

The gas heating path unit 300 should be set to have the temperature of at least 200° C. If the second reaction gas supplied from the reaction gas supplying unit 200 has a temperature of T0 on inducing into the second conveying line P2 and a temperature of T2′ before being induced into the top lid 30, the gas heating path unit 300 should be close to the top lid 30 so that the temperature T2′ is lower than T2 and higher than T0.

In addition, if T2′ satisfies the relation T2>T2′>T0, a value of T2′−T0 should be 20° C. or higher.

Operations S1 through S4 are series of processes of depositing the thin film on the wafer W, and especially, the first and second reaction gases are injected onto the wafer W disposed on the wafer block 20 through the first and second injection holes 21 and 22 in S2 to deposit the thin film on the wafer W.

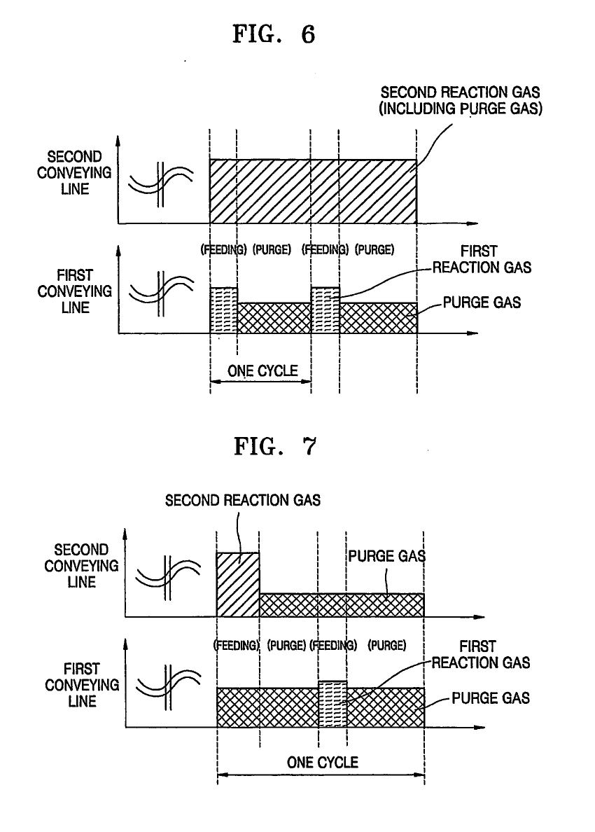

Here, as shown in FIG. 6, operation S2 includes the operations of injecting the first reaction gas regularly and repeatedly through the first injection hole 21 while injecting the second reaction gas onto the wafer W continuously, and injecting a purge gas through the first injection hole 21 between the feeding operations of the first reaction gas.

That is, the second reaction gas is fed into the reaction chamber 100 after being thermally activated or deactivated after passing through the gas heating path unit 300 that is heated to be at least 200° C. or higher. However, the first reaction gas is induced into the reaction chamber 100 in regular pulses, because if the first reaction gas that is generally injected in a vapor form is thermally deactivated, a pyrolysis substitution reaction cannot occur.

The thin film deposition (S2) can be performed by combining the ALD method and the CVD method. That is, the first reaction gas is pulsed regularly while injecting the second reaction gas continuously into the reaction chamber like in the CVD method. The above method has a slower deposition speed than the CVD method, however, a faster deposition speed than the ALD method. That is, according to the above method, the thin film grows by the pyrolysis substitution reaction between the reaction gases and an efficiency of discharging by-products of the reaction is higher than that of the CVD method. Thus, the above method has a higher purity of the thin film than that of the general CVD method, and a higher deposition speed than that of the general ALD method.

As shown in FIG. 7, the thin film deposition (S2) can be performed by the ALD method including feeding the reaction gas by injecting the first reaction gas and the second reaction gas regularly and alternately, and injecting the purge gas through the first injection hole 21 and/or the second injection hole 22 between the feeding periods of the first and second reaction gases. In the operation S2, the second reaction gas is more activated thermally than that in the general ALD method or completely deactivated. In addition, the first reaction gas is induced into the reaction chamber in a state of being appropriately heated like in the general ALD method, and is not completely deactivated.

In the above thin film deposition method, the purge gas is one selected from the group consisting of Ar, He, and N2.

In addition, when the first reaction gas is a precursor including a transition metal element such as Ti, Ta, and W, and the second reaction gas is one selected from the group consisting of N2, NH3, and N2H4, the deposited thin film is a transition metal nitride layer, that is, TiN, TaN, or WN.

When the first reaction gas is the precursor including the transition metal element such as Ti, Ta, and W and the second reaction gas includes H, the deposited thin film is a transition metal tin film, that is, Ti, Ta, and W.

In the post-process S3, the heat treatment gas including the injected H element uses one or more gases selected from the group consisting of N2, NH3, and N2H4.

A second embodiment of the method of depositing the thin film using the thin film deposition apparatus is as follows.

The second embodiment of the method of depositing thin film is performed using the second embodiment of the thin film deposition apparatus. The second embodiment of the thin film deposition apparatus includes the operations of loading the wafer W onto the wafer block 20 (S1), depositing the thin film by injecting the first reaction gas including the transition element and the second reaction gas that is thermally activated or deactivated by the gas heating path unit 300 through the first and second injection holes 21 and 22 (S2), and unloading the wafer W, on which the thin film is deposited, from the wafer block 20.

Here, if it is assumed that the second reaction gas has the temperature of T1 before passing through the gas heating path unit 300 and the temperature of T2 after passing through the gas heating path unit 300, the temperature T2 should be higher than the temperature T1. In addition, the surface temperature of the shower head 40 is controlled by flowing the fluid onto the fluid path 46.

The thermocouple 47 is installed on the shower head 40 or the top lid 30 for measuring the temperature of the shower head 40, and the flowing amount on the fluid path 46 is controlled based on the signal generated by the thermocouple 47. Thus, at any point on the lowermost surface of the shower head 40, the value of maximum temperature—minimum temperature should be maintained within a range of ±25° C.

The surface heater 35 is installed on the upper portion of the top lid 30, and maintains the surface temperature of the shower head 40 within a tolerable range by networking with the thermocouple 47 and the fluid path 46.

The operations of S1, S2, and S4 are the series of processes for depositing the thin film on the wafer W, and especially in S2, the first and second reaction gases are injected onto the wafer W on the wafer block 20 through the first and second injection holes 21 and 22 to deposit the thin film on the wafer W.

An example of the thin film depositing operation S2, as shown in FIG. 6, includes an operation of feeding the gas by injecting the first reaction gas through the first injection hole 21 regularly and repeatedly while injecting the second reaction gas onto the wafer W continuously through the second injection hole 22, and an operation of injecting purge gas through the first injection hole 21 between feeding periods of the first reaction gas.

Another example of the thin film depositing operation S2, as shown in FIG. 7, is the general ALD method including an operation of feeding the gas by injecting the first and second gases regularly and alternately, and injecting the purge gas through the first injection hole 21 and/or the second injection hole 22 between the feeding periods of the first and second reaction gases.

Detailed descriptions for those examples of the thin film depositing operation S2 will be omitted, since these are described in above first embodiment of the thin film deposition method.

In the thin film deposition method, the purge gas is one selected from the group consisting of Ar, He, and N2.

In addition, when the first reaction gas is a precursor including a transition metal element such as Ti, Ta, and W, and the second reaction gas is one selected from a group consisting of N2, NH3, and N2H4, the deposited thin film is a transition metal nitride layer.

When the first reaction gas is the precursor including the transition metal element such as Ti, Ta, and W and the second reaction gas includes H, the deposited thin film is a transition metal tin film.

A third embodiment of the method of depositing the thin film using the above described thin film deposition apparatus is as follows.

The third embodiment of the thin film deposition method according to the present invention is performed using the third embodiment of the thin film deposition apparatus. The thin film deposition method includes the operations of loading the wafer W onto the wafer block 20 (S1), depositing the thin film by injecting the first reaction gas that is thermally activated by the first gas heating path unit 400 and the second reaction gas that is thermally activated or deactivated by the second gas heating path unit 500 through the first and second injection holes 21 and 22 onto the wafer W (S2), and unloading the wafer W, on which the thin film is deposited, from the wafer block 20.

Here, if the first reaction gas has the temperature of T1 before passing through the first gas heating path unit 400 and the temperature of T2 after passing through the first gas heating path unit 400, the temperature T2 is lower than a decomposition temperature of the first reaction gas. In addition, if the second reaction gas has the temperature of T3 before passing through the second gas heating path unit 500 and the temperature of T4 after passing through the second gas heating path unit 500, the temperature T4 is higher than the decomposition temperature of the second reaction gas. In addition, the surface temperature of the shower head 40 is controlled by flowing the fluid through the fluid path 46.

The thermocouple 47 is installed on the shower head 40 or the top lid 30 for measuring the temperature of the shower head 40, and the flowing amount of the fluid path 46 is controlled based on the signal generated by the thermocouple 47. Thus, at any point on the lowermost surface of the shower head 40, the value of maximum temperature—minimum temperature should be maintained within a range of ±25° C.

The surface heater 35 is installed on the upper portion of the top lid 30, and maintains the surface temperature of the shower head 40 within a tolerable range by networking with the thermocouple 47 and the fluid path 46.

The operations of S1, S2, and S4 are the series of processes for depositing the thin film on the wafer W, and especially in S2, the first and second reaction gases are injected onto the wafer W on the wafer block 20 through the first and second injection holes 21 and 22 to deposit the thin film on the wafer W. The first and second reaction gases are injected in the same ways described in the first and second examples of S2.

In the thin film deposition method, the purge gas is one selected from the group consisting of Ar, He, and N2.

In addition, when the first reaction gas is a precursor including a transition metal element such as Ti, Ta, and W, and the second reaction gas is one selected from the group consisting of N2, NH3, and N2H4, the deposited thin film is a transition metal nitride layer.

When the first reaction gas is the precursor including the transition metal element such as Ti, Ta, and W and the second reaction gas includes H, the deposited thin film is a transition metal tin film.

The present invention using the gas heating path unit can be used as a substitution for a conventional NF3 remote plasma cleaning method. That is, in the thin film deposition process, the gas heating path unit heats the reaction gas so that the gas can be thermally activated or deactivated, however, in the plasma cleaning process, the temperature of the gas heating path unit is set higher. Therefore, the NF3 gas molecules passing through the gas heating path unit are thermally activated so that the molecules become active radicals that have very high responsibility, and the NF3 gas of the radical state is diluted with the inert gas and flowed to the reaction chamber. Here, it is desirable that the temperatures of the wafer block and the chamber surface are lowered to prevent the damages thereof.

### INDUSTRIAL APPLICABILITY

As described above, according to the thin film deposition method of the present invention, the thin film having less impurities can be deposited in the low temperature environment without using expensive remote plasma or direct plasma apparatus, and the wafer processing speed can be improved faster to correspond to the lowering of cost of ownership (CoO).

1. A method of depositing a thin film using a thin film deposition apparatus that includes a reaction chamber having a wafer block located in a chamber to heat a loaded wafer up to a predetermined temperature, a top lid covering the chamber to seal the chamber, and a shower head coupled under the top lid and having a first injection hole and a second injection hole, through which a first reaction gas and a second reaction gas are injected into the wafer, a reaction gas supplying unit supplying the first and second reaction gases into the reaction chamber, and a gas heating path unit installed on a second conveying line between first and second conveying lines connecting the reaction chamber and the reaction gas supplying unit to heat the gas passing through itself, the method comprising the operations of:
loading the wafer on the wafer block;
depositing a thin film by injecting the first reaction gas and the second reaction gas that is thermally activated onto the wafer through the first and second injection holes;
flowing a heat treatment gas including an H element onto the thin film to reduce impurities included in the thin film; and
unloading the wafer, on which the thin film is deposited, from the wafer block,
wherein if the second reaction gas has a temperature of T1 before passing through the gas heating path unit and a temperature of T2 after passing through the gas heating path unit, T2 is higher than T1, and if the heat treatment gas has a temperature of T1 before passing through the gas heating path unit and a temperature of T3 after passing through the gas heating path unit, T3 is same as T1 or higher.

2. The method of claim 1, wherein if the second reaction gas supplied from the reaction gas supplying unit has a temperature of T0 right after being induced into the second conveying line and a temperature of T2′ before being induced into the top lid, the gas heating path unit is connected close to the top lid so that T2′ is lower than T2 and higher than T0.

3. The method of claim 2, wherein if T2′ satisfies a relation of T2>T2′>T0, a value of T2′-T0 is at least 20° C. or higher.

4. The method of claim 1, wherein depositing of the thin film comprises:
feeding the gas by injecting the first reaction gas regularly and repeatedly through the first injection hole while injecting the second reaction gas onto the wafer through the second injection hole; and
injecting a purge gas through the first injection hole between the feeding periods of the first reaction gas.

5. The method of claim 1, wherein the depositing of the thin film comprises:
feeding the gas by injecting the first and second reaction gases through the first and second injection holes regularly and alternately, and injecting the purge gas through the first injection hole and/or the second injection hole between the feeding periods of the first and second reaction gases.

6. The method of claim 4, wherein the purge gas is one selected from the group consisting of Ar, He, and N₂.

7. The method of claim 1, wherein the first reaction gas is a precursor including a transition metal element such as Ti, Ta, and W and the second reaction gas is one selected from a group consisting of N₂, NH₃, and N₂H₄.

8. The method of claim 1, wherein the first reaction gas is a precursor including a transition metal element such as Ti, Ta, and W and the second reaction gas is a gas including H.

9. The method of claim 1, wherein the gas heating path unit is set to have a temperature of at least 200° C.

10. The method of claim 1, wherein in the flowing of the heat treatment gas, the heat treatment gas including H element includes one or more selected from the group consisting of N₂, NH₃, and N₂H₄.

11. A method of depositing a thin film using a thin film deposition apparatus that includes a reaction chamber having a wafer block located in a chamber to heat a loaded wafer up to a predetermined temperature, a top lid covering the chamber to seal the chamber, a shower head coupled under the top lid and having a first injection hole and a second injection hole, through which a first reaction gas and a second reaction gas are injected into the wafer, and a fluid path circulating a fluid into the top lid or the shower head, a reaction gas supplying unit supplying the first and second reaction gases into the reaction chamber, and a gas heating path unit installed on a second conveying line between first and second conveying lines connecting the reaction chamber and the reaction gas supplying unit to heat the gas passing through itself, the method comprising the operations of:
loading the wafer on the wafer block;
depositing a thin film by injecting the first reaction gas including a transition element and the second reaction gas that is thermally activated onto the wafer through the first and second injection holes; and
unloading the wafer, on which the thin film is deposited, from the wafer block,
wherein if the second reaction gas has a temperature of T1 before passing through the gas heating path unit and a temperature of T2 after passing through the gas heating path unit, T2 is higher than T1, and the fluid flows through the fluid path to control a surface temperature of the shower head.

12. The method of claim 11, wherein a thermocouple is installed on the shower head or the top lid for measuring the temperature of the shower head, and a flowing amount on the fluid path is varied from a signal generated by the thermocouple, so that a value of maximum temperature—minimum temperature at any point on the lowermost surface of the shower head can be maintained within a range of ±25° C.

13. The method of claim 11, wherein a surface heater is installed on the top lid, and the surface heater maintains the surface temperature of the shower head within a tolerably range by interconnecting with the thermocouple and the fluid path.

14. The method of claim 11, wherein the depositing of thin film comprises:
feeding the gas by injecting the first reaction gas regularly and repeatedly through the first injection hole while injecting the second reaction gas onto the wafer through the second injection hole; and
injecting a purge gas through the first injection hole between the feeding periods of the first reaction gas.

15. The method of claim 11, wherein the depositing of the thin film comprises:
feeding the gas by injecting the first and second reaction gases through the first and second injection holes regularly and alternately, and injecting the purge gas through the first injection hole and/or the second injection hole between the feeding periods of the first and second reaction gases.

16. The method of claim 14, wherein the purge gas is one selected from the group consisting of Ar, He, and N₂.

17. A method of depositing a thin film using a thin film deposition apparatus that includes a reaction chamber having a wafer block located in a chamber to heat a loaded wafer up to a predetermined temperature, a top lid covering the chamber to seal the chamber, a shower head coupled under the top lid and having a first injection hole and a second injection hole, through which a first reaction gas and a second reaction gas are injected into the wafer, and a fluid path circulating a fluid into the top lid or the shower head, a reaction gas supplying unit supplying the first and second reaction gases into the reaction chamber, a first gas heating path unit installed on a first conveying line connecting the reaction chamber and the reaction gas supplying unit to heat the gas passing through itself, and a second gas heating path unit installed on a second conveying line connecting the reaction chamber and the reaction gas supplying unit to heat the gas passing through itself, the method comprising the operations of:
loading the wafer on the wafer block;
depositing a thin film by injecting the first reaction gas that is thermally activated and the second reaction gas that is thermally activated onto the wafer through the first and second injection holes; and
unloading the wafer, on which the thin film is deposited, from the wafer block,
wherein if the first reaction gas has a temperature of T1 before passing through the first gas heating path unit and a temperature of T2 after passing through the first gas heating path unit, T2 is smaller than a decomposition temperature of the first reaction gas,
if the second reaction gas has a temperature of T3 before passing through the second gas heating path unit and a temperature of T4 after passing through the second gas heating path unit, T4 is the decomposition temperature of the second reaction gas or higher,
and the fluid flows through the fluid path to control a surface temperature of the shower head.

18. The method of claim 17, wherein a thermocouple is installed on the shower head or the top lid for measuring the temperature of the shower head, and a flowing amount on the fluid path is varied from a signal generated by the thermocouple, so that a value of maximum temperature—minimum temperature at any point on the lowermost surface of the shower head can be maintained within a range of ±25° C.

19. The method of claim 17, wherein a surface heater is installed on the top lid, and the surface heater maintains the surface temperature of the shower head within a tolerably range by interconnecting with the thermocouple and the fluid path.

20. The method of claim 17, wherein the depositing of thin film comprises:
feeding the gas by injecting the first reaction gas regularly and repeatedly through the first injection hole while injecting the second reaction gas onto the wafer through the second injection hole; and
injecting a purge gas through the first injection hole between the feeding periods of the first reaction gas.

21. The method of claim 17, wherein the depositing of the thin film comprises:
feeding the gas by injecting the first and second reaction gases through the first and second injection holes regularly and alternately, and injecting the purge gas through the first injection hole and/or the second injection hole between the feeding periods of the first and second reaction gases.

22. The method of claim 20, wherein the purge gas is one selected from the group consisting of Ar, He, and N₂.

23. The method of claim 5, wherein the purge gas is one selected from the group consisting of Ar, He, and N₂.

24. The method of claim 15, wherein the purge gas is one selected from the group consisting of Ar, He, and N₂.

25. The method of claim 21, wherein the purge gas is one selected from the group consisting of Ar, He, and N₂.
